(19) United States
(12) Patent Application Publication
(10) Pub. No.: US 2024/0071743 A1
(43) Pub. Date: Feb. 29, 2024

(54) ELECTROCHEMICAL SYSTEMS AND METHODS FOR FINISHING SiC WAFERS

(71) Applicant: Pallidus, Inc., Albany, NY (US)

(72) Inventors: Mark Land, Houston, TX (US); Darren Hansen, Midland, MI (US); Victor Torres, Clifton Park, NY (US); Robert Mervich, Matthews, NC (US); Thomas Kegg, Slingeriands, NY (US)

(73) Assignee: Pallidus, Inc., Albany, NY (US)

(21) Appl. No.: 18/191,037

(22) Filed: Mar. 28, 2023

Related U.S. Application Data
(60) Provisional application No. 63/324,584, filed on Mar. 28, 2022.

(51) Int. Cl. H01L 21/02; H01L 21/3063; H01L 21/67

(52) U.S. Cl. CPC H01L 21/02052; H01L 21/02378; H01L 21/30635; H01L 21/6704

(57) ABSTRACT

Methods and systems for the electrochemical finishing of SiC wafers. Embodiments of these methods use an applied electrical bias, an electrolytic oxidant removal solution and light to remove raised surface features and imperfections of an SiC wafer.

This application claims the right of priority to, and under 35 U.S.C. § 119(e)(1) the benefit of, U.S. provisional application Ser. No. 63/324,584 filed Mar. 28, 2022, the entire disclosure of which is incorporated herein by reference.

### BACKGROUND OF THE INVENTION

### Field of the Invention

The present inventions relate to systems and methods for finishing the surface of Silicon Carbide (SiC) structures and in particular SiC wafers.

In general, the process for making electronic components from SiC boules involves cutting the SiC single crystalline boule into a thin wafer. Typically, the wafer has the diameter of the boule and typically has a thickness of about 100 μm to about 500 μm. The wafers are then finished, e.g., ground, polished, and subjected to other mechanical, chemical and mechanical-chemical processes on one or both sides to finish their surfaces. The finished wafers are then used as substrates for the fabricated of microelectronic semiconductor devices. Thus, the wafer serves as a substrate for microelectronic devices that are built in the wafer, built over the wafer or both. The fabrication of these microelectronic devices includes microfabrication processing steps, such as, epitaxial growth, doping or ion implantation, etching, deposition of various materials, and photolithographic patterning, to name a few. Once fabricated from the wafer, the wafer, and thus the individual microcircuits, is separated, in processes know as dicing, into individual semiconductors devices. These devices are then used in the making of, e.g., incorporated into, various larger semiconductor and electronic devices.

The present inventions provide electrochemical processes that reduce and preferably eliminate these prior costly, time consuming, inefficient, and expensive finishing operations. The present inventions provide electrochemical processes that provide wafers of equal and superior quality, consistency, and at higher yields, than are obtained by these prior finishing processes.

As used herein, unless specified otherwise, “Vapor Deposition” (VD), “vapor deposition technology”, vapor deposition process and similar such terms are to be given their broadest meaning, and would include for example processes where a solid or liquid starting material is transformed into a gas or vapor state, and then the gas or vapor is deposited to form, e.g., grow, a solid material. As used herein vapor deposition technology would include growth by epitaxy, where the layer is provided from a vapor or gaseous phase. Further types of vapor deposition technology include: Chemical Vapor Deposition (CVD); Physical Vapor Deposition (PVD), plasma enhanced CVD, Physical Vapor Transport (PVT) and others. Examples of vapor deposition devices would include a hot wall reactor, a multiwafer reactor, a chimney reactor, an RF furnace, and a boule growth furnace.

As used herein, unless specified otherwise the term “vaporization temperature” is to be given its broadest possible meaning and includes that temperature at which the material transitions from a liquid to a gas state, transitions from a solid to a gas state, or both (e.g., the solid to liquid to gas transition occurs over a very small temperature range, e.g., a range of less than about 20° C., less than about 10° C., and less than about 5° C.). Unless specifically stated otherwise, the vaporization temperature would be the temperatures corresponding to any particular pressures, e.g., one atmosphere, 0.5 atmosphere, where such transition occurs. When discussing the vaporization temperature of a material in a particular application, method, or being used in a particular device, such as a PVT device, the vaporization temperature would be at the pressure used, or typically used, in that application, method or device, unless expressly stated otherwise.

As used herein, unless stated otherwise, room temperature is 25° C. And, standard ambient temperature and pressure is 25° C. and 1 atmosphere. Unless expressly stated otherwise all tests, test results, physical properties, and values that are temperature dependent, pressure dependent, or both, are provided at standard ambient temperature and pressure, this would include viscosities.

Generally, the term “about” and the symbol “—” as used herein unless stated otherwise is meant to encompass the larger of a variance or range of ±10% and the experimental or instrument error associated with obtaining the stated value.

As used herein, unless specified otherwise the terms %, weight % and mass % are used interchangeably and refer to the weight of a first component as a percentage of the weight of the total, e.g., formulation, mixture, preform, material, structure or product. The usage X/Y or XY indicates weight % of X and the weight % of Y in the formulation, unless expressly provided otherwise. The usage X/Y/Z or XYZ indicates the weight % of X, weight % of Y and weight % of Z in the formulation, unless expressly provided otherwise.

As used herein, unless specified otherwise “volume %” and “(% volume” and similar such terms refer to the volume of a first component as a percentage of the volume of the total, e.g., formulation, mixture, preform, material, structure or product.

This Background of the Invention section is intended to introduce various aspects of the art, which may be associated with embodiments of the present inventions. Thus, the forgoing discussion in this section provides a framework for better understanding the present inventions, and is not to be viewed as an admission of prior art.

### SUMMARY

There has been a long-standing and unfulfilled need for methods of making SiC wafers from SiC boules in a cost-effective manner to provide among other things high quality SiC wafers having one, and preferably both surfaces, having high quality and a large percentage of their surfaces available for use in making semiconductor devices. The present inventions, among other things, solve these needs by providing the compositions, materials, articles of manufacture, devices and processes taught, disclosed and claimed herein.

Thus, there is provided an SiC wafer surface finishing system, the system including: a means for moving a surface of an SiC wafer through a beam path of electromagnetic radiation; housing containing the SiC wafer and an electrolytic solution; a source of electromagnetic radiation, configured to provide a beam of electromagnetic radiation along the beam path; and, a means for providing an electrical bias.

Further there is provide these methods and systems having one or more of the following features: wherein the means for moving comprises a turn table, configured to rotate the SiC wafer in the bean path; further comprising a fluid seal between the housing and the turntable; further comprising a window in the housing and located on the beam path, wherein the window is transmissive to the electromagnetic radiation; further comprising a beam dump located on the beam path; wherein the source of electromagnetic radiation is a laser, and the beam of electromagnetic radiation is a laser beam; wherein the further the source of electromagnetic radiation is a light source, and the beam of electromagnetic radiation is a light beam; wherein the further the source of electromagnetic radiation is a UV laser, and the beam of electromagnetic radiation is a laser beam having a wavelength in the UV light range; wherein the source of electromagnetic radiation is a UV light source, and the beam of electromagnetic radiation is a light beam having a wavelength in the UV light range; wherein the electrolytic solution comprises a solvent and a fluoride ion contain material; wherein the electrolytic solution comprises water, an alcohol and hydrofluoric acid; wherein the electrolytic solution comprises water, an alcohol and hydrofluoric acid; wherein the concentration of hydrofluoric acid in the electrolytic solution is from 1% to 50%; wherein the electrolytic solution comprises water, an alcohol and hydrofluoric acid; wherein the concentration of hydrofluoric acid in the electrolytic solution is from 10% to 30%; wherein the electrolytic solution comprises water, an alcohol and hydrofluoric acid; wherein the concentration of hydrofluoric acid in the electrolytic solution is greater than 10%; wherein the means for providing an electrical bias includes an electric potential bias source, a (−) electrode, a (+) electrode and, a reference electrode; wherein the electric potential bias source comprises a battery; and, wherein the means for moving the SiC wafer through the beam path of electromagnetic radiation is a conveyor having a plurality of SiC wafers.

Yet further, there is provided an SiC wafer surface finishing system, the system including: an SiC wafer having a first surface and a second surface; a housing containing the SiC wafer and having a first chamber and second chamber; and a seal separating the first and second chamber; wherein the SiC wafer is positioned in the housing, whereby the first surface is in the first chamber and the second surface is in the second chamber; a source of electromagnetic radiation, configured to provide a beam of electromagnetic radiation along the beam path; wherein the laser beam path is directed to the first surface of the wafer; a means for providing an electrical bias; and, the first chamber containing a first electrolytic solution; and the second chamber containing a second electrolytic solution.

Further there is provide these methods and systems having one or more of the following features: wherein the first and the second electrolytic solution are the same; and wherein the first and the second electrolytic solution are different.

Moreover, there is provided a method of finishing the surface of an SiC wafer, the method including: directing a beam of electromagnetic radiation along a beam path, through an electrolytic solution to the surface of an SiC wafer; wherein the electrolytic solution covers the surface of the wafer at a location of the beam path on the surface of the SiC wafer; providing an electrical bias to the SiC; and, selectively oxidizing raised portions of the SiC wafer surface, thereby removing the raised portions from the surface.

### BRIEF DESCRIPTION OF THE DRAWINGS

FIG. 1 is a side schematic view, with a partial cutaway showing interior components in dashed lines, of an embodiment of an SiC wafer surface finishing system in accordance with the present inventions.

FIG. 1A is a cross sectional schematic view of the system of FIG. 1 taken along line 1A-1A of FIG. 1B.

FIG. 1B is a plan view of the system of FIG. 1.

FIG. 2 is a schematic view of an embodiment of an SiC wafer surface finishing system in accordance with the present inventions.

FIG. 3 is a schematic view of an embodiment of an SiC wafer surface finishing system in accordance with the present inventions.

FIG. 4 is a schematic view of an embodiment of an SiC wafer surface finishing system in accordance with the present inventions.

FIG. 5 is a plan schematic view of an embodiment of an SiC wafer surface finishing system in accordance with the present inventions.

FIG. 5A is a cross sectional schematic view of the system of FIG. 5, taken along line 5A-5A.

FIG. 5B is detailed schematic side view of the relative height of placement of the laser beams of the system of FIG. 5.

### DESCRIPTION OF THE PREFERRED EMBODIMENTS

In general, the present inventions relate to the electrochemical finishing of the surface of Silicon Carbide (SiC) structures, and in particular the surfaces of SiC wafers. In particular, embodiments of the present inventions use photoactivated electrochemical finishing processes and system to carry out these processes, to remove imperfection, marks, defects, etc., from the surface of an SiC wafer, and to provide wafers with exceptionally smooth and uniform surfaces.

The surface characteristics of an SiC wafer are an important factor, if not the most important factor, it determining the ability of the wafer to be used as a starting material for the making of semiconductor devices. The surface characteristics of an SiC wafer determine, among other things, if the wafer is useful to make semiconductor devices and if so, the number of semiconductor devices that can be made from that wafer, e.g., device yield. Thus, it is not surprising that complex, multi-step and costly mechanical, chemical and mechanical-chemical processes and equipment (e.g., mill, machine, grind, polish, smooth, buff, etc.) have been developed and are used to finish a wafer after it has been cut from a larger SiC crystal, e.g., a boule or ingot. These finishing steps are costly, have low yields, and still provide wafers with device yields that are not optimal.

Thus, in general, the present inventions are directed to electrochemical processes, devices and systems for finishing the surface of an SiC wafer after the wafer has been cut from a larger SiC crystal. In particular, and embodiment of the present inventions is directed to the phot activated electrochemical finishing of n-type wafers.

In general, the embodiments of the present inventions can reduce or eliminate, some, most, if not all of the prior finishing equipment, processes and steps (i.e., mechanical, chemical, and mechanical-chemical). These embodiments can provide wafer surfaces that have higher device yields than are obtained from the prior finishing equipment, processes and steps.

Typically SiC wafers are formed by cutting the wafers generally transverse to the c-axis (growth axis) of the crystal. Typically, the wafers, for use in the present electrochemical finishing processes and in particular the present photoactivated electrochemical finishing processes can be on the axis (i.e., on axis) or a few degrees of this axis (i.e., off axis), typically, for off axis wafers, about 0.1 to about 5 degrees off this axis. The wafers can have a thickness of from about 80 μm to about 600 μm, and a diameter of from about 50 mm to about 250 mm, with diameters of about 150 mm being preferred. When cut on, or slightly off axis, the SiC wafers typically have a carbon face or surface and a silicon face or surface. The embodiments of the present inventions can finish the carbon and the silicon face of the wafers. Wafers may also be cut along the growth axis, and in any other orientation to the growth axis. Such wafers can also be finished using embodiments of the present inventions.

Embodiment of the present systems and methods for electrochemical finishing of SiC wafers, can find application with the various polytypes of SiC. Generally, these polytypes fall into two categories—alpha (α) and beta (β) Embodiments of the alpha category of polysilocarb derived SiC typically contains hexagonal (H), rhombohedral (R), trigonal (T) structures and may contain combinations of these. The beta category typically contains a cubic (C) or zincblende structure. Thus, for example, polytypes of polysilocarb derived silicon carbide would include: 3C—SiC (β-SiC or β 3C—SiC), which has a stacking sequence of ABCABC . . . ; 2H—SiC, which has a stacking sequence of ABAB . . . ; 4H—SiC, which has a stacking sequence of ABCBABCB . . . ; and 6H—SiC (a common form of alpha silicon carbide, α 6H—SiC), which has a stacking sequence of ABCACBABCACB . . . . Examples, of other forms of alpha silicon carbide would include 8H, 10H, 16H, 18H, 19H, 15R, 21R, 24H, 33R, 39R, 27R, 48H, and 51R.

Embodiment of the present systems and methods for electrochemical finishing of SiC wafers, can find application with the various types of SiC wafers, including n-type, p-type, semi-insulating and low resistivity.

In general, embodiments of the present inventions use an electrochemical finishing process to remove material from the surface of the wafer and thus reduce surface defects and wafer imperfections. An electrolytic fluid having both an electrolyte and an oxide removing component is placed in contact with the surface of the SiC wafer (e.g., either the carbon face, or the silicon face). An electrical bias (e.g., a voltage) is applied across the wafer such that the back surface, i.e., the surface way from the electrolytic fluid, is provided with a positive (+) charge, and thus functions as an anode; and the other side (side in contact with the electrolytic fluid) is provided with a negative (−) charge and thus functions as a cathode. The electrochemical reaction is then selectively applied to provide a predetermined removal of material from the surface of the wafer in contact with the electrolytic fluid.

As used herein, unless expressly stated otherwise, the “front side” and the “wet side” of the wafer refers to the side of the wafer in contact with the electrolytic fluid; and the “back side” of the wafer refers to the anode or (+) side of the wafer, which is not in contact with the electrolytic fluid.

In an embodiment of a preferred process, is a photoactivated electrochemical finishing processes, in which the wafer is subjected to electromagnetic radiation (e.g., light) having an energy that is larger than the band gap of the SiC material forming the surface of the wafer. In an embodiment the electromagnetic radiation is selectively applied to the wafer to selectively and in a predetermined manner remove SiC material, while the electrical bias is uniformly applied to the wafer. In an embodiment the electrical bias is selectively applied to the wafer to selectively and in a predetermined manner remove SiC material, while the electromagnetic radiation is uniformly applied to the wafer. In an embodiment the electrical bias and the electromagnetic radiation are both selectively applied to the wafer to selectively and in a predetermined manner remove SiC material. In an embodiment the electrical bias and the electromagnetic radiation are both uniformly applied to the wafer to remove the SiC material in a predetermined manner. Embodiments of combinations and variations of the forgoing selective applications of electrical bias and electromagnetic radiation are contemplated.

Depending upon the thickness of the wafer, the type, e.g., wavelength of the electromagnetic radiation, the power of the electromagnetic energy, and the optical properties of the electrolytic fluid, the electromagnetic radiation can be propagated through the electrolytic fluid and directly contact the surface of the wafer. In other embodiments, it is contemplated that the electromagnetic radiation can directly contact the back side of the wafer (i.e., the side not in contact with the electrolytic fluid) and propagate through the wafer, to reach and affect the front side surface of the wafer. In this manner, the electromagnetic radiation initiates the surface material of the SiC wafer to selectively oxidize, and the oxide formed is removed by the oxide removing component of the electrolytic fluid.

The oxide removing component and the electrolyte in the electrolytic fluid can be the same or different materials. Preferably, the electrochemical fluid is a liquid. The electromagnetic radiation can be light, a laser beam, or other forms of electromagnetic energy that impart sufficient energy to the SiC material to excite electron-hole pairs. Preferably, the electromagnetic radiation imparts energy (i.e., W/cm²) that is greater than the band gap of the SiC material. Any wavelength of light may be used; however, UV and visible light are preferred.

By controlling the distribution of the electrical charge in the wafer, the pattern, power and distribution of the electromagnetic radiation, and the concentration of the electrolyte and the oxide removing component, SiC material, which would contribute to, cause, or be related to a surface defect or imperfection, can be selectively removed from the surface of the wafer, thereby reducing or eliminating the defect.

In general, in an embodiment of the present inventions for finishing n-type SiC wafer uses an electrolytic fluid having a solvent and a fluoride ion contain material. Thus, for example water, alcohol and mixtures of these, can be the solvent; and hydrofluoric acid (HF) can be the electrolyte and oxide removal composition. The HF concentrations can range from 0.1% to about 50% HF. Wetting agents may also be added to the electrolytic fluid for better, e.g., quicker, more uniform, wetting of the surface of the wafer. Other electrolytes may also be added to the electrolytic fluid, to control the fluids conductivity.

In general, for this HF type photoactivated electrochemical finishing of SiC wafers requires the presence of holes during the SiC removal process, and has the following chemistry equation:

SiC+4H₂O+8h⁺>SiO₂+CO₂\hat{ }+8H⁺

SiC+4H₂O+8h⁺>SiO+CO\hat{ }+4H⁺

The formed Silicon Dioxide was dissolved by the presence of Hydrofluoric Acid:

SiO₂+6HF>2H⁺+SiF²₆⁻+2H₂O

The wafers that can be finished by the present inventions can have cross sections, e.g., diameters, of from about ½ inch to about 9 inches, from about 2 inches to about 8 inches, from about 1 inch to about 6 inches, greater than about 1 inch, greater than about 2 inches, greater than about 4 inches, about 4 inches, about 6 inches and about 8 inches about 12 inches and about 18 inches. Other sizes, as well as, all values within the range of these sizes, are contemplated.

Embodiments of the present finished SiC wafers, and the microelectronics fabricated from those wafers, find applications and utilizations in among other things, diodes, broad band amplifiers, military communications, radar, telecom, data link and tactical data links, satcom and point-to-point radio power electronics, LEDs, lasers, lighting and sensors. Additionally, these embodiments can find applications and uses in transistors, such High-electron-mobility transistors (HEMT), including HEMT-based monolithic microwave integrated circuit (MMIC). These transistors can employ a distributed (traveling-wave) amplifier design approach, and with SiC's greater band gap, enabling extremely wide bandwidths to be achieved in a small footprint. Thus, embodiments of the present inventions would include these devices and articles that are made from or otherwise based upon the present methods, vapor deposition techniques, and polymer derived SiC, SiC boules, SiC wafers and the microelectronics fabricated from these wafers.

Thus, it is believed and theorized that the benefits and improve features from the use of embodiments of the present electrochemical, and in particular photoactivated electrochemical processes and systems, can enhance and improve, in at least one or more, and preferably all, of the following properties and features, and reduce in at least one or more, and preferably all, of the following deleterious properties or effects:

Bow—a measure of concave or convex deformation of the median surface of a wafer, independent of any thickness variation which may be present. Bow is determined at the center point of the wafer with respect to a reference plane determined by three points equally spaced on a circle whose diameter is 6.35 mm less than the nominal wafer diameter. Bow is a bulk property of the wafer, not a property of an exposed surface. Generally, bow is determined with the wafer in a free, undamped position. (Not to be confused with warp.)

Flatness—for wafer surfaces, the deviation of the front surface, expressed as TIR or maximum FPD, relative to a specified reference plane when the back surface of the wafer is ideally flat, as when pulled down by vacuum onto an ideally clean flat chuck. The flatness of a wafer may be described as: the global flatness; the maximum value of site flatness as measured on all sites; or the percentage of sites which have a site flatness equal to or less than a specified value.

Flatness quality area—that portion of the surface of a wafer over which the specified flatness values apply. The flatness quality area is most frequently defined with an edge exclusion area, a peripheral annulus usually 3 mm wide.

Focal plane deviation (FPD)—the distance parallel to the optical axis from a point on the wafer surface to the focal plane. global flatness—the TIR or maximum FPD within the flatness quality area relative to a specified reference plane.

Maximum FPD—the largest of the absolute values of the focal plane deviations.

Site flatness—the TIR or maximum FPD of the portion of a site which falls within the flatness quality area.

Total indicator reading (TIR)—the smallest perpendicular distance between two planes, both parallel with the reference plane, which enclose all points within a specified flatness quality area or site on the front surface of a wafer.

Total thickness variation (TTV)—the difference between the maximum and minimum thickness values encountered during a scan pattern or a series of point measurements on a wafer.

Warp—the difference between the maximum and minimum distances of the median surface of the wafer from a reference plane encountered during a scan pattern. Warp is a bulk property of the wafer, not a property of an exposed surface. The median surface may contain regions with upward or downward curvature or both. Generally, warp is determined with the wafer in a free, unclamped position. (Not to be confused with bow.)

Striations—helical features on the surface of a silicon wafer associated with local variations in impurity concentration. Such variations are ascribed to periodic differences in dopant incorporation occurring at the rotating solid-liquid interface during crystal growth. Striations are visible to the unaided eye after preferential etching and appear to be continuous under 100× magnification.

Chip—region where material has been removed from the surface or edge of the wafer. The size of a chip is defined by its maximum radial depth and peripheral chord length as measured on an orthographic shadow projection of the specimen outline. Also known as clamshell, conchoidal fracture, edge chip, flake, nick, peripheral chip, peripheral indent, and surface chip.

Contamination—a broad category of foreign matter visible to the unaided eye on the wafer surface. In most cases, it is removable by gas blow off, detergent wash, or chemical action. See also particulate contamination, stain.

Crack—cleavage that extends to the surface of a wafer and which may or may not pass through the entire thickness of the wafer. Also known as fissure; see also fracture.

Cratering—a surface texture of irregular closed ridges with smooth central regions. crow's-foot—intersecting cracks in a pattern resembling a “crow's foot” (Y) on <111> surfaces and a cross (+) on <100> surfaces.

Dimple—a smooth surface depression, larger than 3 mm in diameter, on a wafer surface.

Fracture—a crack with single or multiple lines radiating from a point.

Groove—a shallow scratch with rounded edges, usually the remnant of a scratch not completely removed during polishing.

Haze—a cloudy or hazy appearance attributable to light scattering by concentrations of microscopic surface irregularities such as pits, mounds, small ridges or scratches, particles, etc.

Imbedded abrasive grains—abrasive particles mechanically forced into the surface of the silicon wafer. This type of contamination may occur during slicing, lapping, or polishing.

Indent—an edge defect that extends from the front surface to the back surface of the silicon wafer.

Light point defects (LPD)—individual fine points of reflected light seen when the wafer is illuminated by a narrow-beam light source held perpendicular to the wafer surface.

Mound—irregularly shaped projection with one or more facets. Mounds can be extensions of the bulk material or various forms of contamination, or both. A high density of mounds can also appear as haze.

Orange peel—a large-featured, roughened surface, similar to the skin of an orange, visible to the unaided eye under fluorescent light but not usually under narrow-beam illumination.

Particulate contamination—a form of contamination comprising particles, such as dust, lint, or other material resting on the surface of the wafer and standing out from the surface. May usually be blown off the surface with clean, dry nitrogen.

Pit—a depression in the surface where the sloped sides of the depression meet the wafer surface in a distinguishable manner (in contrast to the rounded sides of a dimple).

Saw blade defect—a roughened area visible after polishing with a pattern characteristic of the saw blade travel. It may be discernible before chemical polishing. Also known as saw mark.

Scratch—a shallow groove or cut below the established plane of the surface, with a length-to-width ratio greater than 5:1. A macroscratch is =0.12 μm in depth and is visible to the unaided eye under both incandescent (narrow-beam) and fluorescent illumination. A microscratch is <0.12 μm in depth and is not visible to the unaided eye under flourescent illumination.

Spike—a tall, thin dendrite or crystalline filament which often occurs at the center of a recess in the surface of an epitaxial layer.

Stain—a form of contamination such as a streak, smudge, or spot which contains foreign chemical compounds such as organics or salts.

Threading Edge Dislocation (TED).

Threading Screw Dislocation (TSD).

Basal Plan Dislocation (BPD).

Micropipes.

Macro-defects in boules.

Carbon inclusions.

Silicon droplets.

Voids.

### EXAMPLES

The following examples are provided to illustrate various embodiments of systems, processes, compositions, applications and materials of the present inventions. These examples are for illustrative purposes, may be prophetic, and should not be viewed as, and do not otherwise limit the scope of the present inventions.

### Example 1

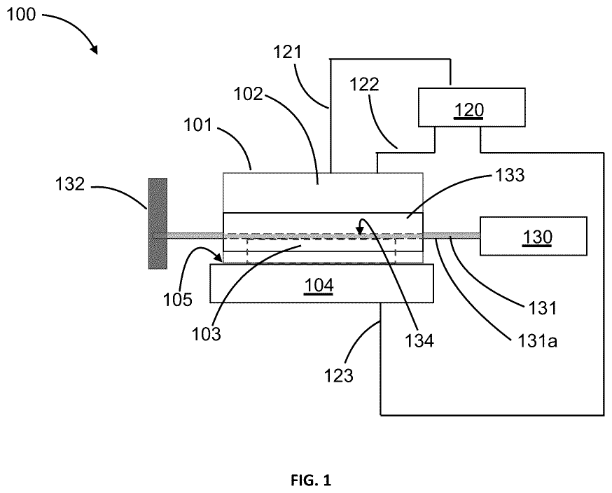

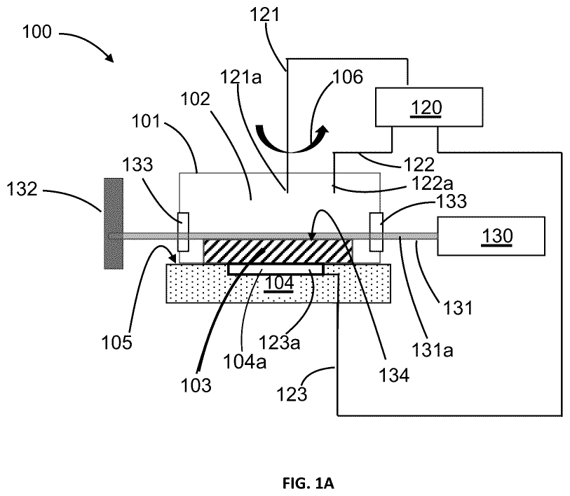

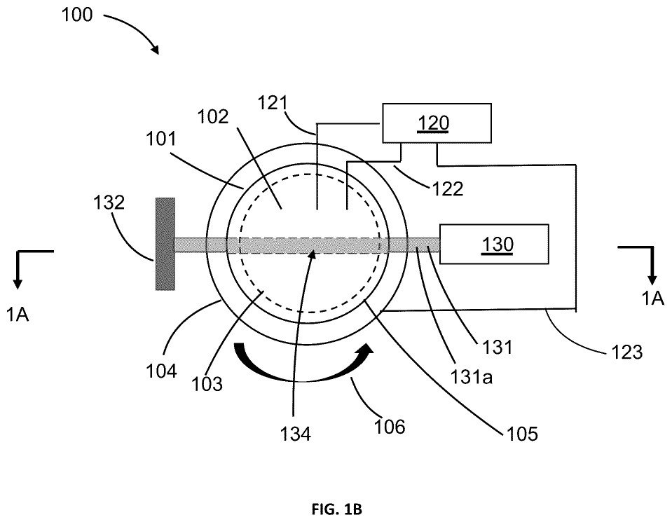

Turning to FIGS. 1, 1A and 1B, there is illustrated an embodiment of a photoactivated electrochemical finishing system and process. The wafer surface finishing system 100, has an outer housing 101 that is in contact with a turntable 104. The outer housing 101 is sealed 105 against the turntable 104, such that, the outer housing 101 and turntable form a liquid tight seal and thus hold and contain the electrolytic fluid 102. The seal 105 extends around the entire point of contact between the housing and turntable, and thus, preferably is outside of the rotating platter 104a of the turntable.

The system 100 has an electric potential bias source 120 (e.g., battery, laptop charger, voltage source). The electrical bias source 120 has lead 121 that connects to electrode 121a to provide a negative potential to the electrolytic fluid 102. The bias source 120 has lead 122 that connects to a reference electrode 122a, which is used to measure potential drop or bias across the SiC wafer 103. The bias source 120 has lead 123 that connects to electrode 123a that provides a positive (anodic) bias to the wafer 103. In the embodiment of this example the wafer 103 can be an n-type wafer and can be a 6-H or 4-H polytype. In this embodiment the platter 104a of turntable 104 also functions as the electrode 123a.

The system 100 has a sources of electromagnetic radiation 130, which in the embodiment of this example is a laser, that provides a laser beam in the UV and visible wavelength. The laser 130 has an optics assembly that shapes and directs the laser beam 131a along a laser beam path 131. The optics assembly can shape the beam to have a cross sectional configuration of a circle, a line, a square, or other shapes. The laser beam can preferably have an M 2 of less than 2 and more preferably 1. The laser beam 131a along the portion of the laser beam path 131 that is over the wafer 103 can be columnated or focused. If the laser beam is focused, it is preferrable that the focal point be positioned and the beam waist be such that the laser beam provides a planar and uniform configuration on its lower side (i.e., side closes to the wafer) which is a uniform distance from the top of the wafer. If the laser beam is columnated the distance between the laser beam and the top of the surface of the wafer should be uniform, across the entire surface of the wafer.

The system 100 has a beam dump 132 in the laser beam path. The beam dump absorbs the laser beam that travels past the wafer. The beam dump provides the ability to prevent the beam from traveling further and prevents the beam from reflecting or scattering back towards the wafer 103.

In operation a wafer 103 is placed inside of housing 101 and is in contact with turntable platter 104a. The housing 101 is filled with electrolytic fluid, for example, an aqueous solution of HF. The turntable 104a is rotated in the direction of arrow 106 and the laser beam 131a is propagated along laser beam path 131. The laser beam travels through window 133. The laser beam contacts raised surface portions 134 of wafer 103, which starts the electrochemical dissolution of the raised surface portion 134, and its removal from the wafer. In this manner as the wafer is rotated all of the raised surface portions 134 will be removed.

The system 100 can be used to further remove a uniform layer from the surface of wafer 103.

It is understood that the electrolytic solution may need to be replenished as it dissolves the SiO₂ that is formed. To the extent that this occurs care should be taken to not create currents or eddies that would change or effect the laser beam path 131, or cause back reflects or scatting of the laser beam.

Additionally, to extent that gas bubbles are formed, a method for managing them should preferrable be included in, or associated with, the housing 101. Additionally, this management means as well as the speed of the rotation of the turntable can be configure to minimize and preferrable prevent any interference (e.g., shattering, reflection, refraction) of the laser beam from the bubbles.

The system 100 may be placed in an additional housing to provided added safety for the use of HF and to provide a system that is eye safe, and does not require the use of laser safety glasses, during operation.

### Example 2

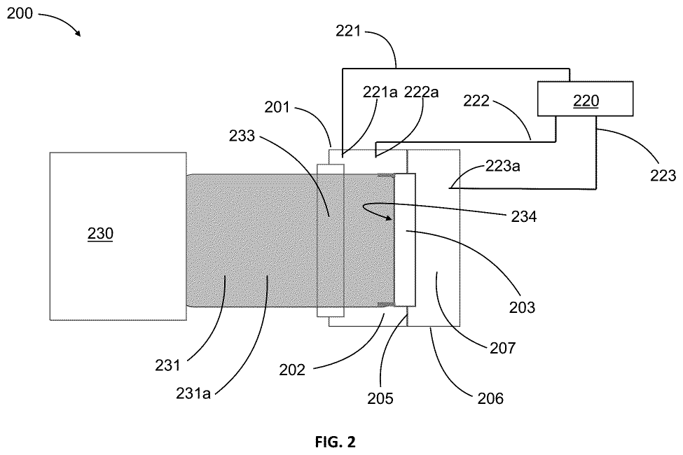

Turning to FIG. 2, there is illustrated an embodiment of a photoactivated electrochemical finishing system and process. The wafer surface finishing system 200, has an outer housing 201 that is in contact with a second outer housing 206. The housings 201 and 206 are separated by a seal 205. The seal 205 can be a membrane, or a flexible or rigid divider, such as a plastic (non-conductive) divider. The system 200 thus has first housing 201 that contains the electrolytic fluid 202 and a second housing 206 that contains an electrolyte 207. The two solutions are electrically and physically separated from each other by the seal 205. The wafer 203 is located on or held by the seal 205, in a manner in which the wafer 203 has its front (wet) surface in contact with the electrolytic solution 202 and its back surface in contact with the electrolyte 207.

The system 200 has an electric potential bias source 220 (e.g., battery, laptop charger, voltage source). The electrical bias source 220 has lead 221 that connects to electrode 221a to provide a negative potential to the electrolytic fluid 102. The bias source 220 has lead 222 that connects to a reference electrode 222a, which is used to measure potential drop or bias across the SiC wafer 203. The bias source 120 has lead 123 that connects to electrode 123a, which is in the electrolyte 206, that provides a positive (anodic) bias to the wafer 203. In the embodiment of this example the wafer 203 can be an n-type wafer and can be a 6-H or 4-H polytype.

The electrolyte 206 can be a liquid, e.g., saline, a gel, or other types of electrolytes, that will provide uniform distribution of the electrical bias across the entire area of the wafer. In embodiments the second housing 206 and electrolyte 207 can be replaced with, or contain a solid electrode, e.g., a metal plate, in direct contact with the wafer.

The system 200 has a sources of electromagnetic radiation 230, which in the embodiment of this example is a light source, that provides a light beam preferably in the UV and visible wavelength. In this embodiment the system 200 can use a laser as the light source, or a light source that provides a beam of non-coherent light. The light can have a very narrow band width, or be broad spectrum light. The light beam 231a is directed along light beam path 231 and is shaped (e.g., by optics assembly) to cover the entire front surface of the wafer 203. The light beam 231a travels through window 233.

In operation a wafer 203 is placed inside of housing 201 and is in contact with seal 205. The housing 201 is filled with electrolytic fluid 202, for example, an aqueous solution of HF. The light beam 231a is propagated along beam path 231. The light beam travels through window 233. The beam 231a contacts the entire surface of the wafer 203. The power of the light, the conductivity of the electrolytic solution 202, the potential source 220 and the electrolyte 207 are controlled in a manner that only raised surface portions 234 of wafer 203, are subjected to electrochemical dissolution and removal from the wafer. In this manner as the wafer is electrochemically processed to provide a uniform surface, free from raised portions 234.

The system 200 can be used to further remove a uniform layer from the surface of wafer 203.

It is understood that the electrolytic solution may need to be replenished as it dissolves the SiO₂ that is formed. In this embodiment, the need to reduce or avoid currents or eddies that would change or effect the beam path 231 is lessened. Back reflects or scatting of the beam, should preferably be avoided.

Additionally, to extent that gas bubbles are formed, a method for managing them should preferrable be included in, or associated with, the housing 201. Additionally, this management means can be configure to minimize and preferrable prevent any interference (e.g., shattering, reflection, refraction) of the light beam from the bubbles.

The system 200 may be placed in an additional housing to provided added safety for the use of HF and to provide a system that is eye safe, and does not require the use of laser safety glasses, during operation.

### Example 3

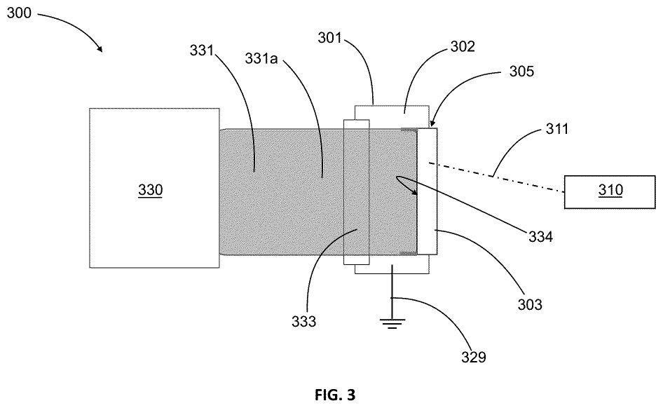

Turning to FIG. 3, there is illustrated an embodiment of a photoactivated electrochemical finishing system and process. The wafer surface finishing system 300, has an outer housing 301. The housings 301 has a seal 305 that is attached to, or provide a seal against the wafer 303. The seal 305 can be a membrane, a gasket, or other assembly such as a plastic (non-conductive) divider. The system 300 thus has first housing 301 that contains the electrolytic fluid 302. In this embodiment the back of the wafer 303 is not in contact with an electrode or an electrolyte solution. The wafer 303 is located on or held by the seal 305, in a manner in which the wafer 203 has its front (wet) surface in contact with the electrolytic solution 202 and a back surface that is not in contact with electrolytic solution 202.

The system 300 has an electron beam propagation device 310 that provides an electron beam 311. The electron beam propitiation device 310 directs, e.g., scans, the electron beam 311 in a predetermined pattern, to predetermined locations on the wafer, to provide localized potential biases in the wafer 303. A ground 329 may also be used. The electron beam can be scanned in a pattern that is based upon the surface defects, e.g., raised portions 334 of the front side of the wafer. Thus, although not shown the system 300 can be integrated with a device to evaluate and measure the topography of the front surface of the wafer and thus, determine, at least in part, the electron beam delivery pattern.

In the embodiment of this example the wafer 303 can be an n-type wafer and can be a 6-H or 4-H polytype. In the embodiment of this example the wafer 303 can be an p-type wafer and can be a 6-H or 4-H polytype.

The system 300 has a sources of electromagnetic radiation 330, which in the embodiment of this example is a light source, that provides a light beam preferably in the UV and visible wavelength. In this embodiment the system 300 can use a laser as the light source, or a light source that provides a beam of non-coherent light. The light can have a very narrow band width, or be broad spectrum light. The light beam 331a is directed along light beam path 331 and is shaped (e.g., by optics assembly) to cover the entire front surface of the wafer 303. The light beam 331a travels through window 333.

In operation a wafer 303 is placed inside of housing 301 and is in contact with seal 305. The housing 301 is filled with electrolytic fluid 302, for example, an aqueous solution of HF. The light beam 331a is propagated along beam path 331. The light beam travels through window 333. The beam 331a contacts the entire surface of the wafer 303. The power of the light, the conductivity of the electrolytic solution 302, the scanning pattern of the electron beam 311 are controlled in a manner that only raised surface portions 334 of wafer 303, are subjected to electrochemical dissolution and removal from the wafer. In this manner as the wafer is electrochemically processed to provide a uniform surface, free from raised portions 334.

The system 300 can be used to further remove a uniform layer from the surface of wafer 303, e.g., by using a raster scan.

It is understood that the electrolytic solution may need to be replenished as it dissolves the SiO₂ that is formed. In this embodiment, the need to reduce or avoid currents or eddies that would change or effect the beam path 331 is lessened. Back reflects or scatting of the beam, should preferably be avoided.

Additionally, to extent that gas bubbles are formed, a method for managing them should preferrable be included in, or associated with, the housing 301. Additionally, this management means can be configure to minimize and preferrable prevent any interference (e.g., shattering, reflection, refraction) of the light beam from the bubbles.

The system 300 may be placed in an additional housing to provided added safety for the use of HF and to provide a system that is eye safe, and does not require the use of laser safety glasses, during operation.

### Example 4

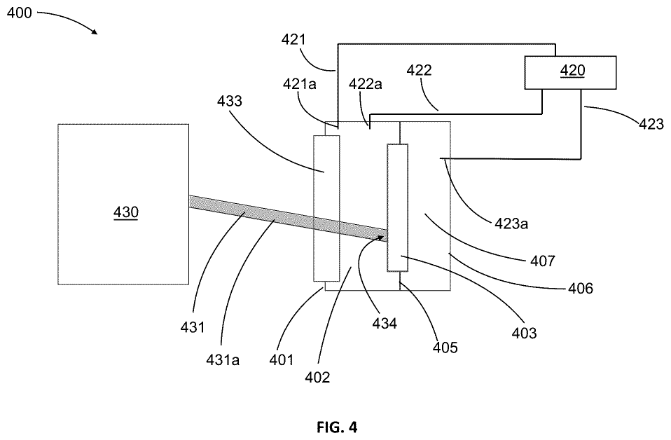

Turning to FIG. 4, there is illustrated an embodiment of a photoactivated electrochemical finishing system and process. The wafer surface finishing system 400, has an outer housing 401 that is in contact with a second outer housing 406. The housings 401 and 406 are separated by a seal 405. The seal 405 can be a membrane, or a flexible or rigid divider, such as a plastic (non-conductive) divider. The system 400 thus has first housing 401 that contains the electrolytic fluid 402 and a second housing 406 that contains an electrolyte 407. The two solutions are electrically and physically separated from each other by the seal 405. The wafer 403 is located on or held by the seal 405, in a manner in which the wafer 403 has its front (wet) surface in contact with the electrolytic solution 402 and its back surface in contact with the electrolyte 407.

The system 400 has an electric potential bias source 420 (e.g., battery, laptop charger, voltage source). The electrical bias source 420 has lead 421 that connects to electrode 421a to provide a negative potential to the electrolytic fluid 102. The bias source 420 has lead 422 that connects to a reference electrode 422a, which is used to measure potential drop or bias across the SiC wafer 403. The bias source 420 has lead 423 that connects to electrode 423a, which is in the electrolyte 406, that provides a positive (anodic) bias to the wafer 403. In the embodiment of this example the wafer 403 can be an n-type wafer and can be a 6-H or 4-H polytype.

The electrolyte 406 can be a liquid, e.g., saline, a gel, or other types of electrolytes, that will provide uniform distribution of the electrical bias across the entire area of the wafer. In embodiments the second housing 406 and electrolyte 407 can be replaced with, or contain a solid electrode, e.g., a metal plate, in direct contact with the wafer.

The system 400 has a source of electromagnetic radiation 430, which in the embodiment of this example is a laser, that provides a laser beam in the UV and visible wavelength. The laser 430 has an optics assembly that shapes and directs and scans the laser beam 431a along a laser beam path 431 in a predetermined laser beam pattern. The optics assembly can shape the beam to have a laser beam spot having a cross sectional configuration of a circle, a line, a square, or other shapes. The laser beam can preferably have an M 2 of less than 2 and more preferably 1. The laser beam 431a is directed along the laser beam path 431 to deliver a laser beam spot to the front surface of the wafer.

In operation a wafer 403 is placed inside of housing 401 and is in contact with seal 405. The housing 401 is filled with electrolytic fluid 402, for example, an aqueous solution of HF. The light beam 431a is propagated along beam path 131. The light beam travels through window 433. The beam 431a provides a laser beam spot that contacts the surface of the wafer 403 and is scanned across that surface in a predetermined manner. The scanning pattern, and the placement of laser beam spot, as well as, power of the light, the conductivity of the electrolytic solution 402, the potential source 420 and the electrolyte 407 are controlled in a manner that only raised surface portions 434 of wafer 403, are subjected to electrochemical dissolution and removal from the wafer. In this manner as the wafer is electrochemically processed to provide a uniform surface, free from raised portions 434.

The system 400 can be used to further remove a uniform layer from the surface of wafer 403, e.g., a raster scan pattern.

It is understood that the electrolytic solution may need to be replenished as it dissolves the SiO₂ that is formed. To the extent that this occurs care should be taken to not create currents or eddies that would change or effect the laser beam path 431, or cause back reflects or scatting of the laser beam.

Additionally, to extent that gas bubbles are formed, a method for managing them should preferrable be included in, or associated with, the housing 401. Additionally, this management means can be configure to minimize and preferrable prevent any interference (e.g., shattering, reflection, refraction) of the light beam from the bubbles.

The system 400 may be placed in an additional housing to provided added safety for the use of HF and to provide a system that is eye safe, and does not require the use of laser safety glasses, during operation.

### Example 5

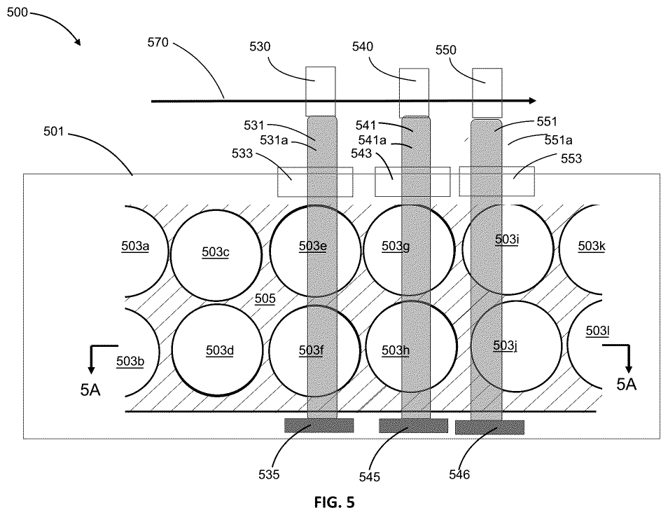

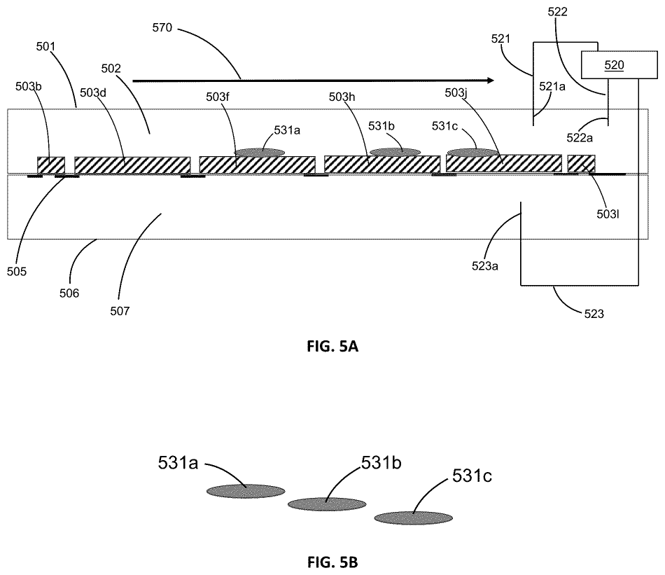

Turning to FIGS. 5, 5A and 5B there is shown an embodiment of a wafer finishing system 500 that is configured for use in the continuous finishing of a large number of wafers. The system 500 has three laser assemblies (items 530 to 535, items 540 to 545, and items 550 to 555). The turntable of the embodiment of FIG. 1 has been replaced with a seal moving surface 505, e.g., a conveyor. FIG. 5B shows the relative height of the laser beams 531a, 531b and 531c with respect to the surface of the wafers.

### Example 6

The systems and process of Examples 1 to 5 are used to provide an SiC wafer having the following features.

| | |
|---|---|
| Parameter | N Type |
| Polytype | 4H |
| Dopant | Nitrogen |
| Resistivity | ~0.02 Ohm-cm |
| Orientation | 40 off axis |
| FWHM | <20 arc sec |
| Roughness, Ra | <5 A |
| Dislocation Density | ~3 × 103 cm−2 |
| Micropipe Density | <0.1 cm−2 |

### Example 7

The systems and process of Examples 1 to 5 are used to provide an SiC wafer having the following features.

| Polytype | 4H | | |
|---|---|---|---|
| Dopant | Nitrogen | | |
| Surface Orientation | 3.5 to 4.5 | | |
| Diameter | 149.8 to 150.2 | | |
| Primary Flat Position | +/−1 | | |
| Flat Length | 45-50 or 55-60 | | |
| Bow | +/−30 | | |
| Warp | <50 | | |
| TTV | <10 | | |
| SBIR | <5 | | |
| SFQR | NA | | |
| Resistivity | 0.014 to 0.024 | 0.014 to 0.023 | 0.014 to 0.022 |
| Foreign Polytype | 0 | 0 | 0 |
| Total Usable Area | >90 | >95 | >97 |
| EPD | <15,000 | <12,000 | <9,000 |
| TED | <10,000 | <9000 | <8000 |
| TSD | <3000 | <500 | <400 |
| BPD | <5000 | <4000 | <3000 |
| MPD | <1 | <0.5 | <0.3 |
| Surface and crystal imperfections | <5 | <5 | <5 |
| Hex Plates | 0 | 0 | 0 |
| Visual Carbon Inclusions | <0.05% | <0.05% | <0.05% |
| Scratches | <40 | <40 | <40 |

| | |
|---|---|
| Edge Chips and indents | 0 |
| Cracks | 0 |
| Pinholes | 0 |
| Pits | <20 |
| Si Face Finish | <0.5 |
| C Face Finish | <5 |
| Metal Levels | <1e11 |
| Contamination | None |

### Example 8

An electrochemical finishing process is applied to the surface of an epitaxy layer of SiC. For example, the systems of Examples 1 to 5 are used to process the epitaxy layer.

### Example 9

An electrochemical finishing process is applied to an SiC surface of an multilayer structure having one, two, three or more layers. For example, the systems of Examples 1 to 5 are used to process the multiplayer structure.

### Example 10

Combinations and variations of the embodiments of Examples 1 to 5.

### Example 11

An electrochemical finishing process is used to finish and polish the edge of an SiC wafer. For example, the systems of Examples 1 to 5 are used to provide high edge quality, and further, in an embodiment, can be configured to focus, or be directed, specifically on the wafer edges.

### Headings and Embodiments

It should be understood that the use of headings in this specification is for the purpose of clarity, and is not limiting in any way. Thus, the processes and disclosures described under a heading should be read in context with the entirely of this specification, including the various examples. The use of headings in this specification should not limit the scope of protection afford the present inventions.

It is noted that there is no requirement to provide or address the theory underlying the novel and groundbreaking processes, materials, performance or other beneficial features and properties that are the subject of, or associated with, embodiments of the present inventions. Nevertheless, various theories are provided in this specification to further advance the art in this area. These theories put forth in this specification, and unless expressly stated otherwise, in no way limit, restrict or narrow the scope of protection to be afforded the claimed inventions. These theories many not be required or practiced to utilize the present inventions. It is further understood that the present inventions may lead to new, and heretofore unknown theories to explain the function-features of embodiments of the methods, articles, materials, devices and system of the present inventions; and such later developed theories shall not limit the scope of protection afforded the present inventions.

The various embodiments of formulations, articles, materials, parts, wafers, boules, volumetric structure, uses, applications, equipment, methods, activities, and operations set forth in this specification may be used for various other fields and for various other activities, uses and embodiments. Additionally, these embodiments, for example, may be used with: existing systems, articles, compositions, materials, operations or activities; may be used with systems, articles, compositions, materials operations or activities that may be developed in the future; and with such systems, articles, compositions, materials, operations or activities that may be modified, in-part, based on the teachings of this specification. Further, the various embodiments and examples set forth in this specification may be used with each other, in whole or in part, and in different and various combinations. Thus, for example, the configurations provided in the various embodiments and examples of this specification may be used with each other; and the scope of protection afforded the present inventions should not be limited to a particular embodiment, example, configuration or arrangement that is set forth in a particular embodiment, example, or in an embodiment in a particular Figure.

The invention may be embodied in other forms than those specifically disclosed herein without departing from its spirit or essential characteristics. The described embodiments are to be considered in all respects only as illustrative and not restrictive.

1. An SiC wafer surface finishing system, the system comprising:
a. a means for moving a surface of an SiC wafer through a beam path of electromagnetic radiation;
b. a housing containing the SiC wafer and an electrolytic solution;
c. a source of electromagnetic radiation, configured to provide a beam of electromagnetic radiation along the beam path; and,
d. a means for providing an electrical bias.

2. The SiC wafer surface finishing system of claim 1, wherein the means for moving comprises a turn table, configured to rotate the SiC wafer in the bean path.

3. The SiC wafer surface finishing system of claim 1, further comprising a fluid seal between the housing and the turntable.

4. The SiC wafer surface finishing system of claim 1, further comprising a window in the housing and located on the beam path, wherein the window is transmissive to the electromagnetic radiation.

5. The SiC wafer surface finishing system of claim 1, further comprising a beam dump located on the beam path.

6. The SiC wafer surface finishing system of claim 1, wherein the source of electromagnetic radiation is a laser, and the beam of electromagnetic radiation is a laser beam.

7. The SiC wafer surface finishing system of claim 1, wherein the further the source of electromagnetic radiation is a light source, and the beam of electromagnetic radiation is a light beam.

8. The SiC wafer surface finishing system of claim 1, wherein the further the source of electromagnetic radiation is a UV laser, and the beam of electromagnetic radiation is a laser beam having a wavelength in the UV light range.

9. The SiC wafer surface finishing system of claim 1, wherein the source of electromagnetic radiation is a UV light source, and the beam of electromagnetic radiation is a light beam having a wavelength in the UV light range.

10. The SiC wafer surface finishing system of claim 1, wherein the electrolytic solution comprises a solvent and a fluoride ion contain material.

11. The SiC wafer surface finishing system of claim 1, wherein the electrolytic solution comprises water, an alcohol and hydrofluoric acid.

12. The SiC wafer surface finishing system of claim 1, wherein the electrolytic solution comprises water, an alcohol and hydrofluoric acid; wherein the concentration of hydrofluoric acid in the electrolytic solution is from 1% to 50%.

13. The SiC wafer surface finishing system of claim 1, wherein the electrolytic solution comprises water, an alcohol and hydrofluoric acid; wherein the concentration of hydrofluoric acid in the electrolytic solution is from 10% to 30%.

14. The SiC wafer surface finishing system of claim 1, wherein the electrolytic solution comprises water, an alcohol and hydrofluoric acid; wherein the concentration of hydrofluoric acid in the electrolytic solution is greater than 10%.

15. The SiC wafer surface finishing system of claim 1, wherein the means for providing an electrical bias comprises:
a. an electric potential bias source;
b. a (−) electrode;
c. a (+) electrode; and,
d. a reference electrode.

16. The SiC wafer surface finishing system of claim 15, wherein the electric potential bias source comprises a battery.

17. The SiC wafer surface finishing system of claim 1, wherein the means for moving the SiC wafer through the beam path of electromagnetic radiation is a conveyor having a plurality of SiC wafers.

18. An SiC wafer surface finishing system, the system comprising:
a. an SiC wafer having a first surface and a second surface;
b. a housing containing the SiC wafer and having a first chamber and second chamber; and a seal separating the first and second chamber;
c. wherein the SiC wafer is positioned in the housing, whereby the first surface is in the first chamber and the second surface is in the second chamber;
d. a source of electromagnetic radiation, configured to provide a beam of electromagnetic radiation along the beam path;
wherein the laser beam path is directed to the first surface of the wafer;
e. a means for providing an electrical bias; and,
f. the first chamber containing a first electrolytic solution; and
the second chamber containing a second electrolytic solution.

19. The SiC wafer surface finishing system of claim 18, wherein the first and the second electrolytic solution are the same.

20. The SiC wafer surface finishing system of claim 18, wherein the first and the second electrolytic solution are different.

21. The SiC wafer surface finishing system of claim 18, further comprising a window in the housing and located on the beam path, wherein the window is transmissive to the electromagnetic radiation.

22. The SiC wafer surface finishing system of claim 18, further comprising a beam dump located on the beam path.

23. The SiC wafer surface finishing system of claim 18, wherein the source of electromagnetic radiation is a laser, and the beam of electromagnetic radiation is a laser beam.

24. The SiC wafer surface finishing system of claim 18, wherein the source of electromagnetic radiation is a light source, and the beam of electromagnetic radiation is a light beam.

25. The SiC wafer surface finishing system of claim 18, wherein the source of electromagnetic radiation is a UV laser, and the beam of electromagnetic radiation is a laser beam having a wavelength in the UV light range.

26. The SiC wafer surface finishing system of claim 18, wherein the source of electromagnetic radiation is a UV light source, and the beam of electromagnetic radiation is a light beam having a wavelength in the UV light range.

27. The SiC wafer surface finishing system of claim 18, wherein the first electrolytic solution comprises a solvent and a fluoride ion contain material.

28. The SiC wafer surface finishing system of claim 18, wherein the first electrolytic solution comprises water, an alcohol and hydrofluoric acid.

29. The SiC wafer surface finishing system of claim 18, wherein the first electrolytic solution comprises water, an alcohol and hydrofluoric acid; wherein the concentration of hydrofluoric acid in the electrolytic solution is from 1% to 50%.

30. The SiC wafer surface finishing system of claim 18, wherein the first electrolytic solution comprises water, an alcohol and hydrofluoric acid; wherein the concentration of hydrofluoric acid in the electrolytic solution is from 10% to 30%.

31. The SiC wafer surface finishing system of claim 18, wherein the first electrolytic solution comprises water, an alcohol and hydrofluoric acid; wherein the concentration of hydrofluoric acid in the electrolytic solution is greater than 10%.

32. The SiC wafer surface finishing system of claim 18, wherein the means for providing an electrical bias comprises:
a. an electric potential bias source;
b. a (−) electrode;
c. a (+) electrode; and,
d. a reference electrode.

33. The SiC wafer surface finishing system of claim 32, wherein the electric potential bias source comprises a battery.

34. The SiC wafer surface finishing system of claim 32, wherein the (+) electrode comprises the second electrolytic solution.

35. A method of finishing the surface of an SiC wafer, the method comprising:
a. directing a beam of electromagnetic radiation along a beam path, through an electrolytic solution to the surface of an SiC wafer; wherein the electrolytic solution covers the surface of the wafer at a location of the beam path on the surface of the SiC wafer;
b. providing an electrical bias to the SiC; and,
c. selectively oxidizing raised portions of the SiC wafer surface, thereby removing the raised portions from the surface.

36. The method of claim 35, wherein the beam of electromagnetic radiation is a laser beam.

37. The method of claim 35, wherein the beam of electromagnetic radiation is the beam of electromagnetic radiation is a light beam.

38. The method of claim 35, wherein the beam of electromagnetic radiation is a laser beam having a wavelength in the UV light range.

39. The method of claim 35, wherein the beam of electromagnetic radiation is a light beam having a wavelength in the UV light range.

40. The method of claim 35, wherein the electrolytic solution comprises a solvent and a fluoride ion contain material.

41. The method of claim 35, wherein the electrolytic solution comprises water, an alcohol and hydrofluoric acid.

42. The method of claim 35, wherein the electrolytic solution comprises water, an alcohol and hydrofluoric acid; wherein the concentration of hydrofluoric acid in the electrolytic solution is from 1% to 50%.

43. The method of claim 35, wherein the electrolytic solution comprises water, an alcohol and hydrofluoric acid; wherein the concentration of hydrofluoric acid in the electrolytic solution is from 10% to 30%.

44. The method of claim 35, wherein the electrolytic solution comprises water, an alcohol and hydrofluoric acid; wherein the concentration of hydrofluoric acid in the electrolytic solution is greater than 10%.
